(19) United States
(12) Patent Application Publication
(10) Pub. No.: US 2017/0207172 A1
(43) Pub. Date: Jul. 20, 2017

(54) ELECTRONIC COMPONENT PACKAGE AND METHOD OF MANUFACTURING THE SAME

(71) Applicant: SAMSUNG ELECTRO-MECHANICS CO., LTD., Suwon-si (KR)

(72) Inventor: Sang Min LEE, Suwon-si (KR)

(21) Appl. No.: 15/278,935

(22) Filed: Sep. 28, 2016

(30) Foreign Application Priority Data
Jan. 15, 2016 (KR) 10-2016-0005467

(51) Int. Cl. H01L 23/538; H01L 23/00; H01L 23/48; H01L 21/768; H01L 21/683; H01L 21/56; H01L 21/3213; H01L 23/31; H01L 25/065

(52) U.S. Cl. CPC H01L 23/5389; H01L 23/3128; H01L 24/20; H01L 23/481; H01L 23/3135; H01L 23/3114; H01L 25/0657; H01L 24/19; H01L 21/6835; H01L 21/568; H01L 21/32133; H01L 21/76802; H01L 21/76877; H01L 2221/68359; H01L 2225/06548; H01L 2224/215; H01L 2924/01029; H01L 2924/01013; H01L 2924/01047; H01L 2924/0105; H01L 2924/01079; H01L 2924/01028; H01L 2924/01082; H01L 2924/3025

(57) ABSTRACT

An electronic component package includes an electronic component disposed on a wiring part, an encapsulant encapsulating the electronic component, a first conductive connection structure penetrating through the encapsulant to thereby be connected to the wiring part and having an upper surface disposed at a level below an upper surface of the encapsulant to form a step structure, and a second conductive connection structure filling the step structure to thereby be connected to the first conductive connection structure.

### CROSS-REFERENCE TO RELATED APPLICATION(S)

This application claims benefit of priority to Korean Patent Application No. 10-2016-0005467 filed on Jan. 15, 2016 in the Korean Intellectual Property Office, the disclosure of which is incorporated herein by reference in its entirety.

### TECHNICAL FIELD

The present disclosure relates an electronic component package and a method of manufacturing the same.

### BACKGROUND

An electronic component package is defined as type of package technology for electrically connecting an electronic component to a printed circuit board (PCB) such as a main board of an electronic device, or the like, and protecting the electronic component from external impacts. Meanwhile, one of the main recent trends within the technological field related to the development of electronic components is to reduce the size of electronic components. Therefore, in the field of packaging, and in accordance with a rapid increase in demand for compact electronic components, or the like, the implementation of an electronic component package having a small size and including a plurality of pins has been demanded.

One type of package technology suggested in order to satisfy the technical demand as described above is a wafer level package (WLP) using a redistribution wiring of an electrode pad of an electrode component formed on a wafer. Examples of wafer level packages include a fan-in wafer level package and a fan-out wafer level package. In particular, the fan-out wafer level package has a compact size and is advantageous in implementing a plurality of pins. Therefore, recently, fan-out wafer level packages have been actively developed.

In the case of such a semiconductor package, the necessity to increase a density of memories, passive elements, or the like, in order to reduce a size of the package and secure high performance has increased. Therefore, an attempt to more finely and precisely form wiring patterns has been continuously conducted.

### SUMMARY

An aspect of the present disclosure may provide an electronic component package having an increased density of electronic components by including a stable electrical connection structure and implementing micropatterns.

Another aspect of the present disclosure may provide a method of manufacturing an electronic component package capable of efficiently manufacturing the electronic component package described above.

According to an aspect of the present disclosure, an electronic component package may include: an electronic component disposed on a wiring part; an encapsulant encapsulating the electronic component; a first conductive connection structure penetrating through the encapsulant to thereby be connected to the wiring part and having an upper surface disposed at a level below an upper surface of the encapsulant to form a step structure; and a second conductive connection structure filling the step structure to thereby be connected to the first conductive connection structure.

According to another aspect of the present disclosure, a method of manufacturing an electronic component package may include: disposing a first conductive connection structure on a support; disposing an electronic component on the support; forming an encapsulant encapsulating the first conductive connection structure and the electronic component on the support; forming a wiring part connected to the first conductive connection structure on the electronic component; removing the support to expose surfaces of the encapsulant and the first conductive connection structure; etching the exposed surface of the first conductive connection structure to form a step structure having a shape recessed from a surface of the encapsulant; and filling a second conductive connection structure in the step structure so as to be connected to the first conductive connection structure.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a block diagram schematically illustrating an example of an electronic device system;

FIG. 2 is a view schematically illustrating an example of an electronic component package used in an electronic device;

FIG. 3 is a cross-sectional view schematically illustrating an example of an electronic component package;

FIGS. 4 through 8 are views schematically illustrating a method of manufacturing an electronic component package according to an exemplary embodiment in the present disclosure; and

FIGS. 9 and 10 are views schematically illustrating a method of manufacturing an electronic component package according to a modified example in the present disclosure.

### DETAILED DESCRIPTION

Hereinafter, exemplary embodiments of the present disclosure will now be described in detail with reference to the accompanying drawings.

Electronic Device

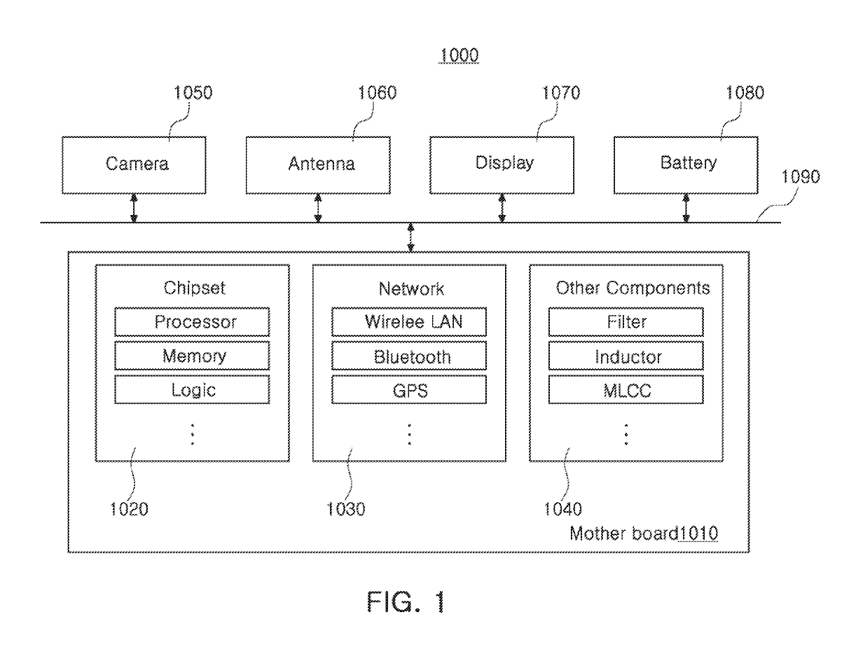

FIG. 1 is a block diagram schematically illustrating an example of an electronic device system. Referring to FIG. 1, an electronic device 1000 may accommodate a main board 1010 therein. Chip related components 1020, network related components 1030, other components 1040, and the like, may be physically and/or electrically connected to the main board 1010. These components may be connected to other components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, etc.; an application processor chip such as a central processor (for example, a central processing unit (CPU)), a graphics processor (for example, a graphic processing unit (GPU)), a digital signal processor, a cryptographic processor, a micro processor, a micro controller, etc.; a logic chip such as an analog-to-digital converter, an application-specific integrated circuit (ASIC), etc.; and the like. However, the chip related components 1020 are not limited thereto, but may also include other types of chip related components. In addition, these components 1020 may be combined with each other.

The network related components 1030 may include protocols such as wireless fidelity (Wi-Fi) (Institute of Electrical and Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, 5G protocols and any other wireless and wired protocols designated after the above-mentioned protocols. However, the network related components 1030 are not limited thereto, but may also include any of a plurality of other wireless or wired standards or protocols. In addition, these components 1030 may be combined with each other together with the chip related components 1020 described above.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), and the like. However, other components 1040 are not limited thereto, but may also include passive components used for various other purposes, and the like. In addition, these components 1040 may be combined with each other together with the chip related components 1020 and/or the network related components 1030 described above.

The electronic device 1000 may include other components that are or are not physically and/or electrically connected to the main board 1010 depending on a kind thereof. These other components may include, for example, a camera 1050, an antenna 1060, a display 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage (for example, a hard disk drive) (not illustrated), a compact disk (CD) (not illustrated), a digital versatile disk (DVD) (not illustrated), and the like. However, these other components are not limited thereto, but may also include other components used for various purposes depending on a kind of electronic device 1000.

The electronic device 1000 may be a smartphone, a personal digital assistant, a digital video camera, a digital still camera, a network system, a computer, a monitor, a tablet, a laptop, a netbook, a television, a video game console, a smart watch, or the like. However, the electronic device 1000 is not limited thereto, but may also be any other electronic device processing data.

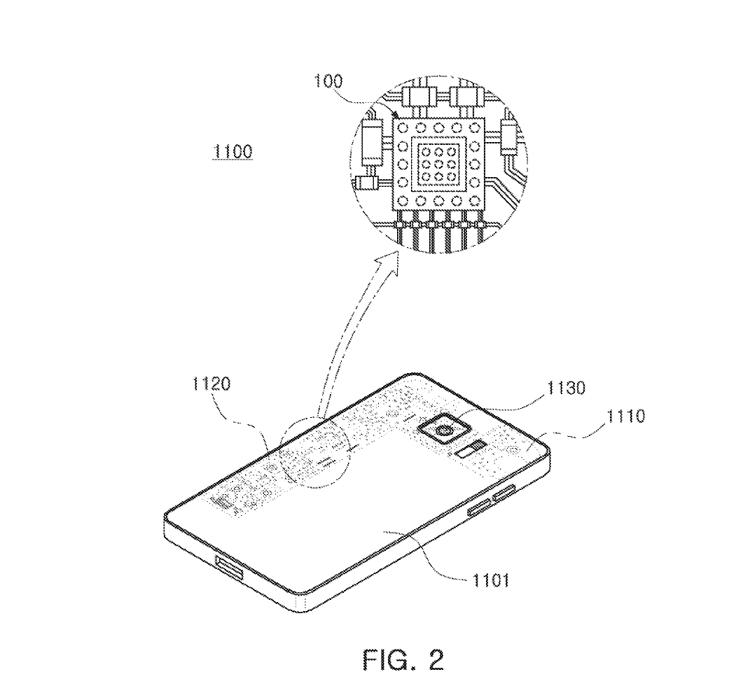

FIG. 2 is a view schematically illustrating an example of an electronic component package used in an electronic device. The electronic component package may be used for various purposes in the various electronic devices 1000 as described above. For example, a main board 1110 may be accommodated in a body 1101 of a smartphone 1100, and various electronic components 1120 maybe physically and/or electrically connected to the main board 1110. In addition, another component that may be or may not be physically and/or electrically connected to the main board 1010, such as a camera 1130, may be accommodated in the body 1101. Here, some of the electronic components 1120 may be the chip related components as described above, and the electronic component package 100 may be, for example, an application processor among the chip related components, but is not limited thereto.

Electronic Component Package

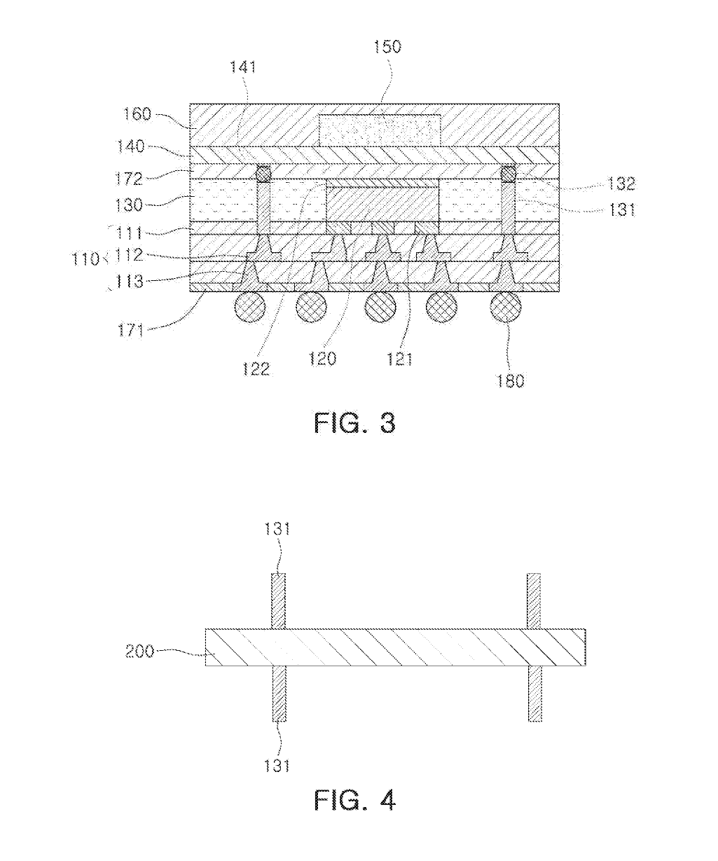

FIG. 3 is a cross-sectional view schematically illustrating an example of an electronic component package. An electronic component package 100 according to the present exemplary embodiment may include a wiring part 110, an electronic component 120, an encapsulant 130, and conductive connection structures 131 and 132 as main components.

The wiring part 110 may provide a disposition region of the electronic component 120, and may be electrically connected to the electronic component 120. In this case, the wiring part 110 may serve to redistribute a wiring structure of the electronic component 120. As an example, the wiring part 110 may include insulating layers 111, conductive patterns 112, and conductive vias 113. A case in which the wiring part 110 has a multilayer structure has been described in an example of FIG. 3, but the wiring part 110 may also be formed of a single layer, if necessary. In addition, the wiring part 110 may also have more layers, depending on design particulars.

An insulating material that may be contained in the insulating layer 111 may be a thermosetting resin such as an epoxy resin, a thermoplastic resin such as a polyimide resin, a resin having a reinforcement material such as a glass fiber or an inorganic filler impregnated in the thermosetting resin and the thermoplastic resin, such as pre-preg, Ajinomoto Build up Film (ABF), FR-4, Bismaleimide Triazine (BT), or the like. In addition, in a case in which a photo-imagable dielectric (PID) is used as the insulating material, the insulating layer 111 may be formed at a thinner thickness, and a micropattern may be more easily implemented. The insulating layers 111 constituting respective layers in the wiring part 110 may be formed of the same material or may be formed of different materials, if necessary. Thicknesses of the insulating layers 111 are also not particularly limited. For example, thicknesses of the insulating layers 111 except for the conductive patterns 112 may be about 5 μm to 20 μm, and thicknesses of the insulating layers 111 when considering thicknesses of the conductive patterns 112 may be about 15 μm to 70 μm.

The conductive patterns 112 may serve as a wiring pattern and/or a pad pattern, and an electrically conductive material such as copper (Cu), aluminum (Al), silver (Ag), tin (Sn), gold (Au), nickel (Ni), lead (Pd), or alloys thereof, may be used as a material of the conductive patterns 112. The conductive patterns 112 may perform various functions depending on a design of the corresponding layers. For example, the conductive patterns 112 may serve as a ground (GND) pattern, a power (PWR) pattern, a signal (S) pattern, and the like, as redistribution patterns. Here, the signal (S) pattern may include various signals except for the ground (GND) pattern, the power (PWR) pattern, and the like, such as data signals, and the like. In addition, the conductive patterns 112 may serve as a via pad, an external connection terminal pad, and the like, as pad patterns. Thicknesses of the conductive patterns 112 are also not particularly limited, but may be, for example, about 10 μm to 50 μm.

Meanwhile, a surface treatment layer may be further formed on conductive patterns 112 exposed to the outside of the insulating layers 111 among the conductive patterns 112, for example, the conductive patterns 112 connected to the electronic component 120, if necessary. The surface treatment layer is not particularly limited as long as it is known in the related art, and may be formed by, for example, electrolytic gold plating, electroless gold plating, electroless tin plating, electroless silver plating, electroless nickel plating/substituted gold plating, or the like.

The conductive vias 113 may electrically connect the conductive patterns 112, and the like, formed on different layers to each other, thereby forming an electrical path within the electronic component package 100. A conductive material such as copper (Cu), aluminum (Al), silver (Ag), tin (Sn), gold (Au), nickel (Ni), lead (Pd), or alloys thereof, may be used as a material of the conductive via 113. The conductive via 113 may also be completely filled with a conductive material. Alternatively, a conductive material may be formed along walls of the conductive via 113. In addition, the conductive via 113 may have all of the shapes known in the related art, such as a tapered shape in which a diameter of the conductive via becomes small toward a lower surface, a reverse tapered shape in which a diameter of the conductive via becomes large toward a lower surface, a cylindrical shape, and the like.

The electronic component 120 may be disposed on the wiring part 110, and may be various active components (such as a diode, a vacuum tube, a transistor, and the like) or passive components (such as an inductor, a condenser, a resistor, and the like). Alternatively, the electronic component 120 may be an integrated circuit (IC) indicating a chip in which hundreds to millions or more of elements are integrated. The electronic component 120 may also be an electronic component in which an integrated circuit is packaged in a flip-chip form, if necessary. The integrated circuit may be an application processor chip such as a central processor (such as a CPU), a graphics processor (such as a GPU), a digital signal processor, a cryptographic processor, a micro processor, a micro controller, or the like, but is not limited thereto. In this case, a form in which one electronic component 120 is mounted on the wiring part 110 has been illustrated in FIG. 3, but two or more electronic components may also be used. In addition, as illustrated in FIG. 3, the electronic component 120 may include electrode pads 121 formed on one surface, that is, an active surface, thereof. The electrode pads 121 may be disposed to be directed toward the wiring part 110.

The encapsulant 130 may encapsulate the electronic component 120 in order to protect the electronic component 120, or the like. In this case, the encapsulant 130 may be formed to cover the electronic component 120 and the wiring part 110, as illustrated in FIG. 3. For example, a thermosetting resin such as an epoxy resin, a thermoplastic resin such as a polyimide resin, a resin having a reinforcement material such as a glass fiber or an inorganic filler impregnated in the thermosetting resin and the thermoplastic resin, such as pre-preg, ABF, FR-4, BT, a PID resin, or the like, may be used as a material of the encapsulant 130. In addition, the encapsulant 130 may be formed by a method of stacking a resin film in a non-hardened state on the wiring part 110 and then hardening the resin film. The encapsulant 130 may be formed by the known molding method such as a method of using an epoxy molding compound (EMC), or the like, in addition to the above-mentioned method.

Meanwhile, the encapsulant 130 may contain conductive particles in order to block electromagnetic waves, if necessary. For example, the conductive particle may be any material that may block electromagnetic waves, such as copper (Cu), aluminum (Al), silver (Ag), tin (Sn), gold (Au), nickel (Ni), lead (Pd), solder, or the like, but is not particularly limited thereto.

In a case of the present exemplary embodiment, the electronic component package may include structures for electrical connection between upper and lower portions. In detail, first conductive connection structures 131 may penetrate through the encapsulant 130 to thereby be connected to the wiring part 110. In this case, the first conductive connection structures 131 may have upper surfaces that are at a level below an upper surface of the encapsulant 130 to form step structures. This form is illustrated in more detail in FIG. 8 illustrating a method of manufacturing an electronic component package. As an example of this structure, as illustrated in FIG. 3, the first conductive connection structures 131 may be conductive posts formed of copper (Cu), or the like. However, as described below, the first conductive connection structures 131 may also have a form of a solder ball rather than the conductive post.

Second conductive connection structures 132 may be filling the step structures formed by the first conductive connection structures 131 and the encapsulant 130 to thereby be connected to the first conductive connection structures 131. In addition, the second conductive connection structures 132 may also be electrically connected to conductive patterns 141 of an additional wiring part 140 formed above the encapsulant 130. As in the present exemplary embodiment, the second conductive connection structures 132 may be filled in and connected to the step structures having a groove form to thereby be stably coupled to the first conductive connection structures 131, and the possibility that the second conductive connection structures 132 will contact other parts adjacent thereto may be reduced, which is appropriate for implementing micropatterns. The second conductive connection structure 132 may be an adhesive electrical connection material such as the solder ball as illustrated in FIG. 3.

An adhesive layer 122 may be formed on an upper surface of the electronic component 120 although it is not a requisite component in the present exemplary embodiment. In this case, as described above, the upper surface of the electronic component 120 may be a non-active surface on which the electrode pads 121 are not formed. The purpose of the adhesive layer 122 may be to fix the electronic component 120 in a process of manufacturing the electronic component package, and an upper surface of the adhesive layer 122 and the upper surface of the encapsulant 130 maybe coplanar with each other, as illustrated in FIG. 3.

Other component will be described. An additional electronic component 150 such as a memory, a passive element, or the like, may be disposed on the encapsulant 130, such that a package-on-package structure may be implemented. To this end, the additional wiring part 140 may be provided above the encapsulant 130. In this case, the additional wiring part 140 may be manufactured in a substrate form and be coupled to the encapsulant 130 through the second conductive connection structures 132, or the like. Alternatively, the additional wiring part 140 may also be formed directly on the encapsulant 130. In this case, the additional wiring part 140 may include insulating layers, conductive patterns, conductive vias, and the like, similar to the wiring part 110. In addition, as illustrated in FIG. 3, an additional encapsulant 160 protecting the additional electronic component 150 may be provided.

In addition, an insulating intermediate layer 172 contacting the adhesive layer 122 may be formed on the encapsulant 130. The insulating intermediate layer 172 may not only protect the additional wiring part 140 disposed thereon, but also improve adhesion performance between the additional wiring part 140 and the encapsulant 130. In this case, the insulating intermediate layer 172 may be formed of a material such as a solder resist.

Meanwhile, an external layer 171 and connection terminals 180 may be provided on an outer layer of the wiring part 110. The external layer 171 may serve to protect the wiring part 110, and the like, from physical and chemical influences, and may have openings exposing at least portions of the conductive patterns 112. A material of the external layer 171 is not particularly limited. For example, a solder resist may be used as a material of the external layer 171. In addition, the same material as that of the insulating layer 111 may be used as a material of the external layer 171, and the external layer 171 is generally a single layer, but may also be multiple layers, if necessary.

The purpose of the connection terminals 180 may be to externally physically and/or electrically connect the electronic component package 100. For example, the electronic component package 100 may be mounted on the main board of the electronic device through the connection terminals 180. In addition, the connection terminals 180 may be connected to another package or electronic component, and functions of the connection terminals 180 may be changed depending on a design scheme.

The connection terminal 180 may be formed of a conductive material, for example, copper (Cu), aluminum (Al), silver (Ag), tin (Sn), gold (Au), nickel (Ni), lead (Pd), solder, or the like, but is not particularly limited thereto. The connection terminal 180 may be a land, a ball, a pin, or the like. The connection terminal 180 may be formed of multiple layers or a single layer. In a case in which the connection terminal 180 is formed of multiple layers, the connection terminal 180 may contain a copper pillar and a solder, and in a case in which the connection terminal 180 is formed of a single layer, the connection terminal 180 may contain a tin-silver solder or copper. However, this is only an example, and the connection terminal 180 is not limited thereto.

Meanwhile, some of the connection terminals 180 may be disposed in a fan-out region. The fan-out region is defined as a region except for a region in which the electronic component is disposed. That is, the electronic component package 100 according to an example may be a fan-out package. The fan-out package may have reliability greater than that of a fan-in package, may implement a plurality of I/O terminals, and may easily perform 3D interconnection. In addition, since the fan-out package may be mounted on the electronic device without using a separate substrate as compared to a ball grid array (BGA) package, a land grid array (LGA) package, or the like, the fan-out package may be manufactured at a reduced thickness, and may have excellent price competitiveness.

Method of Manufacturing Electronic Component Package

Hereinafter, a method of manufacturing an electronic component package according to an example of the present disclosure will be described. The structure of the electronic component package according to the above-mentioned exemplary embodiment or a modified example maybe more clearly understood through a description for a method of manufacturing an electronic component package.

FIGS. 4 through 8 are views schematically illustrating a method of manufacturing an electronic component package according to an exemplary embodiment in the present disclosure.

First, as illustrated in FIG. 4, the first conductive connection structures 131, for example, the conductive posts formed of copper (Cu), or the like, may be formed on a support 200. The purpose of the support 200 may be to easily handle the electronic component, or the like, in a subsequent process, and a material of the support 200 is not particularly limited as long as the support 200 may support the wiring part 100. The support 200 may have a multilayer structure, and may include a release layer, a metal layer, and the like, so as to be easily removed from the wiring part 110 in a subsequent process. In addition, in the present exemplary embodiment, both surfaces of the support 200 may be used to manufacture the electronic component package, thereby securing process efficiency. However, in another exemplary embodiment, only one surface of the support 200 may also be used.

The first conductive connection structures 131 may be formed by attaching a plurality of supports such as posts that have been manufactured in advance onto the support 200 or may be directly formed on the support 200. However, the first conductive connection structures 131 is not necessarily formed in the present process, but may also be formed after the electronic component 120 is disposed or after the encapsulant 130 is formed.

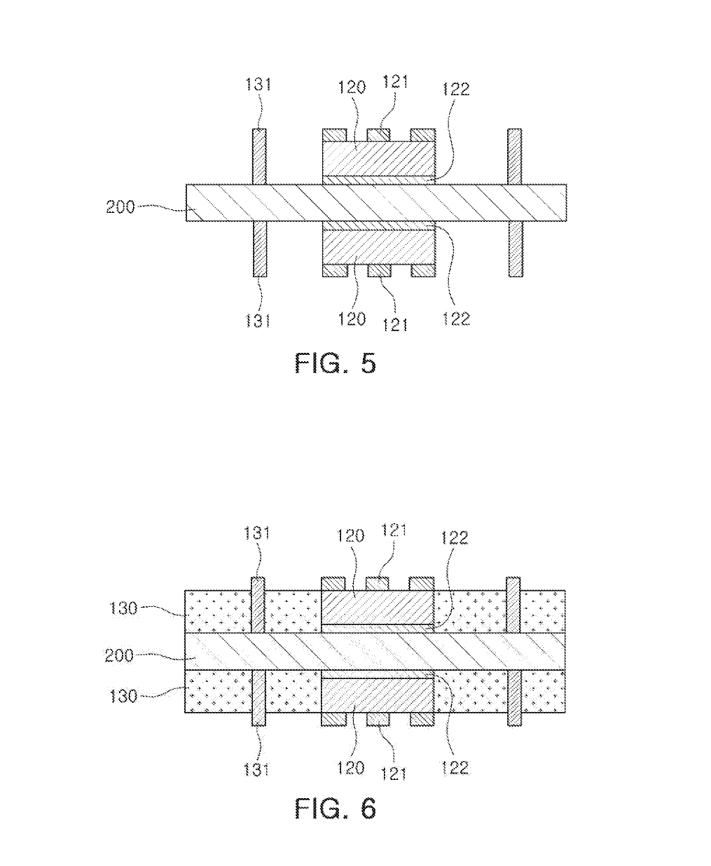

Next, as illustrated in FIG. 5, the electronic component 120 may be disposed and mounted on the support 200, and the adhesive layer 122 may be disposed between the support 200 and the electronic component 120 in order to obtain a stable coupling structure. In this case, the electrode pads 121 of the electronic component 120 may be disposed to face away from the support 200 such that an additional electronic component 150 may be disposed later. Therefore, the non-active surface of the electronic component 120 corresponding to an opposite surface to a surface on which the electrode pads 121 are formed may be directed toward the support 200, and may be coupled to the adhesive layer 122. Then, the wiring part 110 maybe formed in a region from which the support 200 is removed, such that a form illustrated in FIG. 3 may be obtained.

Next, as illustrated in FIG. 6, the encapsulant 130 may be formed by stacking sheets formed of polypropylene glycol (PPG), Ajinomoto build-up film (ABF), or the like, or using a molding process, or the like. In this case, the encapsulant 130 may be formed to cover the first conductive connection structures 131 and the electronic component 120 and be then partially removed by an appropriate polishing process, thereby exposing the first conductive connection structures 131 and the electrode pads 121.

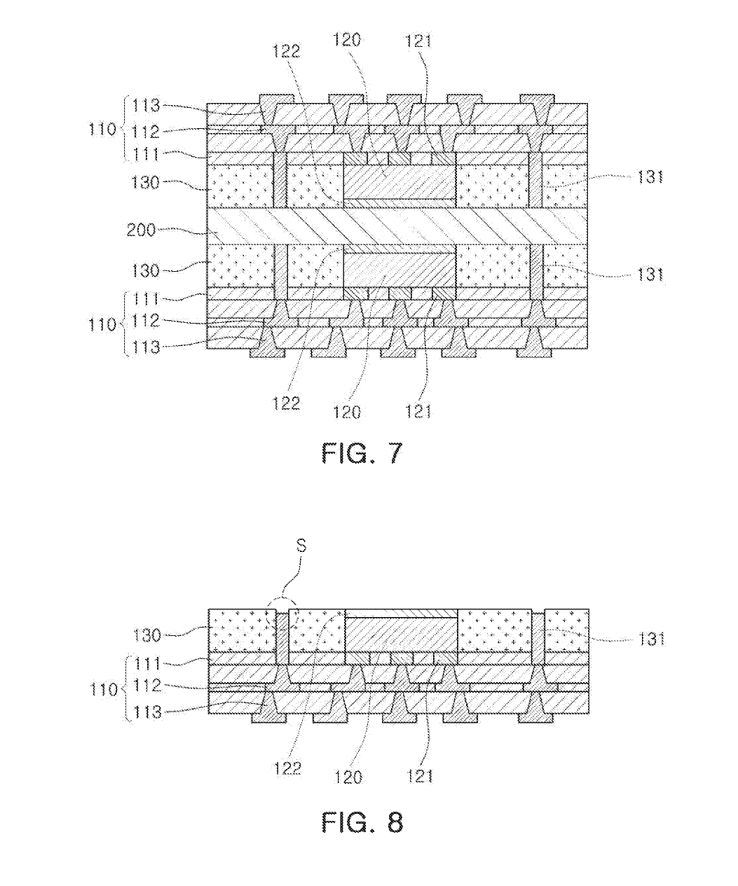

Next, as illustrated in FIG. 7, the wiring part 110 may be formed to be connected to the first conductive connection structures 131. As described above, the wiring part 110 may include the insulating layers 111, the conductive patterns 112, and the conductive vias 113. In order to implement the wiring part 110, the insulating layer 111, the conductive patterns 112, and the conductive vias 113 may be formed depending on intended shapes, and a process of forming the insulating layer 111, the conductive patterns 112, and the conductive vias 113 may be repeated by the required number of times. In detail, the insulating layer 111 may be formed by the known method, for example, a method of laminating a precursor of the insulating layer 111 and then hardening the precursor, a method of applying a material for forming the insulating layer 111 and then hardening the material, or the like. As the method of laminating the precursor, for example, a method of performing a hot press process of pressing the precursor for a predetermined time at a high temperature, decompressing the precursor, and then cooling the precursor to room temperature, cooling the precursor in a cold press process, and then separating a work tool, or the like, maybe used. As the method of applying the material, for example, a screen printing method of applying ink by a squeegee, a spray printing method of applying ink in a mist form, or the like, may be used. The hardening process, which is a post-process, may be a process of drying the material so as not to be completely hardened in order to use a photolithography method, or the like.

Next, as illustrated in FIG. 8, the support 200 may be removed to expose surfaces of the encapsulant 130 and the first conductive connection structures 131. Then, the exposed surfaces of the first conductive connection structures 131 may be etched to form the step structures Shaving a shape recessed from the surface of the encapsulant 130. The first conductive connection structures 131 may be etched using a general chemical etching process or physical process known in the related art.

Meanwhile, in a process of removing the support 200, materials remaining after the support 200 is separated may be removed by appropriately utilizing an etching process, a desmear process, or the like, used in the related art. However, the support 200 may also be removed before the present process. For example, the support 200 may also be removed after the encapsulant 130 is formed. In addition, the support 200 is removed, such that the adhesive layer 122 may also be exposed, and the upper surfaces of the adhesive layer 122 and the encapsulant 130 may be coplanar with each other as described above.

After the step structures S are formed, the second conductive connection structures 132 having a form such as a solder ball, or the like, may be filling the step structures S, and the additional wiring part, the additional electronic component, and the like, maybe disposed above the encapsulant, thereby obtaining a structure illustrated in FIG. 3.

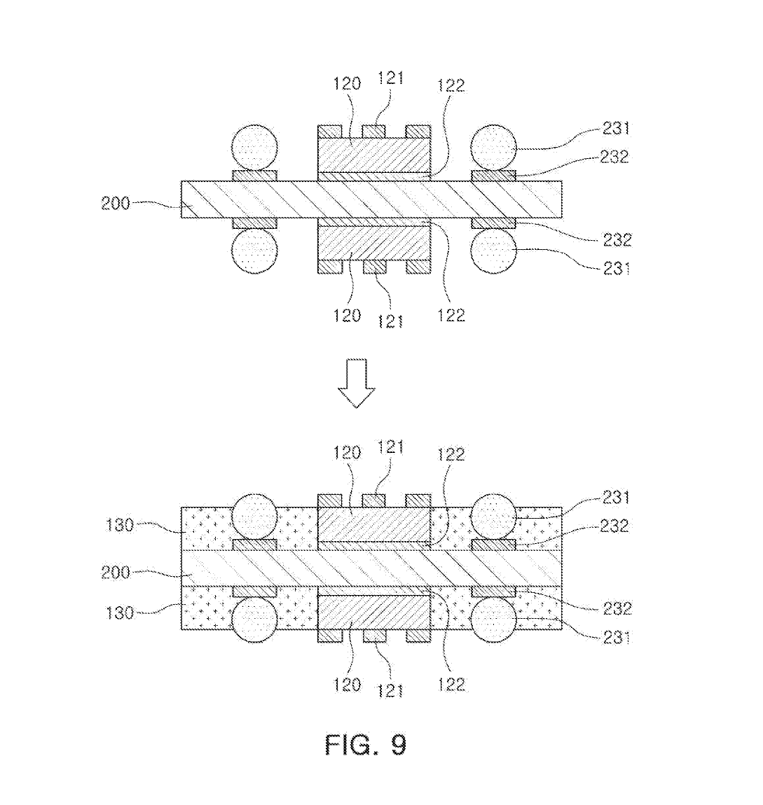

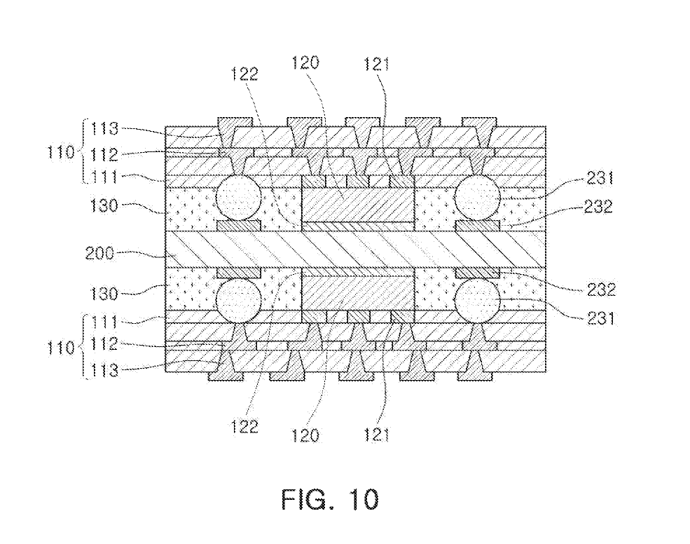

Meanwhile, as described above, the first conductive connection structures 131 may have a form rather than a form of the conductive post, which will be described with reference to FIGS. 9 and 10. In the present modified example, as illustrated in FIGS. 9 and 10, first conductive connection structures 231 may be provided in a form of a solder ball rather than the conductive post. In this case, electrode pads 232 on which the first conductive connection structures 231 are disposed may be formed on the support 200. Then, processes of forming the encapsulant 130 and the wiring part 110, processes of removing the support 200 and forming the step structures and the second conductive connection structures 132, and the like, may be used, similar to the exemplary embodiment described above.

As set forth above, according to an exemplary embodiment in the present disclosure, an electronic component package having improved electrical stability, a small size, and an increased density of electronic components may be obtained. Further, the electronic component package described above may be efficiently manufactured by the method of manufacturing an electronic component package according to an exemplary embodiment in the present disclosure.

While exemplary embodiments have been shown and described above, it will be apparent to those skilled in the art that modifications and variations could be made without departing from the scope of the present invention as defined by the appended claims.

What is claimed is:

1. An electronic component package comprising:
an electronic component disposed on a wiring part;
an encapsulant encapsulating the electronic component;
a first conductive connection structure penetrating through the encapsulant to thereby be connected to the wiring part and having an upper surface disposed at a level below an upper surface of the encapsulant to form a step structure; and
a second conductive connection structure filling the step structure to thereby be connected to the first conductive connection structure.

2. The electronic component package of claim 1, further comprising an adhesive layer formed on an upper surface of the electronic component.

3. The electronic component package of claim 2, wherein an upper surface of the adhesive layer and the upper surface of the encapsulant are coplanar with each other.

4. The electronic component package of claim 2, further comprising an insulating external layer formed on the encapsulant and contacting the adhesive layer.

5. The electronic component package of claim 1, wherein the electronic component includes electrode pads formed on one surface thereof, the electrode pads being disposed in a direction toward the wiring part and electrically connected to conductive patterns of the wiring part.

6. The electronic component package of claim 1, wherein the wiring part includes an insulating layer, a conductive pattern formed on the insulating layer, and a conductive via penetrating through the insulating layer to thereby be connected to the conductive pattern.

7. The electronic component package of claim 1, wherein the first conductive connection structure is a conductive post.

8. The electronic component package of claim 1, wherein the first conductive connection structure is a solder ball.

9. The electronic component package of claim 1, wherein the second conductive connection structure is an adhesive electrical connection material.

10. The electronic component package of claim 9, wherein the second conductive connection structure is a solder ball.

11. The electronic component package of claim 1, further comprising an additional wiring part and an additional electronic component disposed on the encapsulant.

12. A method of manufacturing an electronic component package, comprising:
disposing a first conductive connection structure on a support;
disposing an electronic component on the support;
forming an encapsulant encapsulating the first conductive connection structure and the electronic component on the support;
forming a wiring part connected to the first conductive connection structure on the electronic component;
removing the support to expose surfaces of the encapsulant and the first conductive connection structure;
etching the exposed surface of the first conductive connection structure to form a step structure having a shape recessed from a surface of the encapsulant; and
filling a second conductive connection structure in the step structure so as to be connected to the first conductive connection structure.

13. The method of claim 12, wherein the disposing of the electronic component on the support includes adhering the electronic component to the support with an adhesive layer.

14. The method of claim 12, wherein the electronic component includes an electrode pad formed on one surface thereof, and a surface of the electronic component opposing one surface of the electronic component on which the electrode pad is formed is directed toward the support.

15. The method of claim 12, wherein the forming of the wiring part includes:
forming one or more insulating layers;
forming conductive vias penetrating through the insulating layers; and
forming conductive patterns on the insulating layers.

16. The method of claim 12, wherein the disposing of the first conductive connection structure includes forming a conductive post or a solder ball on the support.
